(19) United States
(12) Patent Application Publication
(10) Pub. No.: US 2010/0091155 A1
(43) Pub. Date: Apr. 15, 2010

(54) Image Sensor and Method for Manufacturing the Same

(76) Inventors: HEE SUNG SHIM, Gangwon-do (KR); Joon Hwang, Chungcheongbuk-do (KR); Jong Min Kim, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/575,855

(22) Filed: Oct. 8, 2009

(30) Foreign Application Priority Data
Oct. 14, 2008 (KR) 10-2008-0100576

(51) Int. Cl. H04N 5/335; H01L 21/768

(52) U.S. Cl. 348/294; 438/98; 257/E21.575

(57) ABSTRACT

An image sensor is provided. The image sensor comprises a readout circuitry, an interconnection, an insulating layer, an electrode, and an image sensing device. The readout circuitry is disposed in a first substrate. The interconnection is disposed over the first substrate and electrically connected to the readout circuitry. The insulating layer is disposed over the interconnection. The electrode is disposed on the insulating layer. The image sensing device is disposed on the electrode. The electrode and the interconnection provide a capacitive coupling of the image sensing device to the readout circuitry so that a contact formation process to contact the photodiode to the interconnection can be omitted.

### CROSS-REFERENCE TO RELATED APPLICATION

This application claims the benefit under 35 U.S.C. §119 of Korean Patent Application No. 10-2008-0100576, filed Oct. 14, 2008, which is hereby incorporated by reference in its entirety.

### BACKGROUND

The present disclosure relates to an image sensor and a method for manufacturing the same.

An image sensor is a semiconductor device for converting an optical image into an electric signal. The image sensor may be roughly classified into a charge coupled device (CCD) image sensor and a complementary metal oxide semiconductor (CMOS) image sensor (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light called Airy disk.

As an alternative to overcome this limitation, an attempt of forming a photodiode using amorphous silicon (Si), or forming a readout circuitry in a silicon (Si) substrate using a method such as wafer-to-wafer bonding and forming a photodiode on and/or over the readout circuitry has been made (referred to as a “three-dimensional (3D) image sensor”). The photodiode is connected with the readout circuitry through a metal interconnection.

According to a related-art, a poor contact between a photodiode and an interconnection may occur, requiring a contact process between the photodiode and the interconnection. In this case, there is a limitation in that a dark current may increases according to the formation of the contact.

In addition, since both the source and the drain of the transfer transistor are heavily doped with N-type impurities in a related art, a charge sharing phenomenon occurs. When the charge sharing phenomenon occurs, the sensitivity of an output image is reduced and an image error may be generated. Also, because a photo charge does not readily move between the photodiode and the readout circuitry, a dark current is generated and/or saturation and sensitivity is reduced.

### BRIEF SUMMARY

Embodiments provide an image sensor and a method for manufacturing the same, which capacitively connects an image sensing device to a readout circuitry.

Embodiments also provide an image sensor and a method for manufacturing the same, which can increase a fill factor and avoid a charge sharing phenomenon.

Embodiments also provide an image sensor that can minimize a dark current source and inhibit saturation reduction and sensitivity degradation by forming a smooth transfer path of photo charges between a photodiode and a readout circuit, and a method for manufacturing the same.

In one embodiment, an image sensor comprises: a readout circuitry in a first substrate; an interconnection over the first substrate and electrically connected to the readout circuitry; an insulating layer over the interconnection; an electrode on the insulating layer; and an image sensing device on the electrode.

In another embodiment, a method for manufacturing an image sensor comprises: forming a readout circuitry in a first substrate; forming an interconnection over the first substrate and electrically connected to the readout circuitry; forming an image sensing device at a second substrate; sequentially forming an electrode and an insulating layer on the image sensing device; and bonding the first substrate and the second substrate to contact the insulating layer with the first substrate.

In still another embodiment, a method for manufacturing an image sensor comprises: forming a readout circuitry in a first substrate; forming an interconnection over the first substrate, the interconnection being electrically connected to the readout circuitry; sequentially forming an insulating layer and an electrode over the interconnection, the electrode being separated from the interconnection by the insulating layer; forming an image sensing device at a second substrate; and bonding the first substrate and the second substrate to contact the electrode with image sensing device.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIGS. 2-8 are cross-sectional views of a method for manufacturing an image sensor according to a first embodiment.

FIGS. 9 and 10 are circuit diagrams for an image sensor according to an embodiment.

FIG. 11 is a cross-sectional view of an image sensor according to another embodiment.

### DETAILED DESCRIPTION

Hereinafter, embodiments of an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

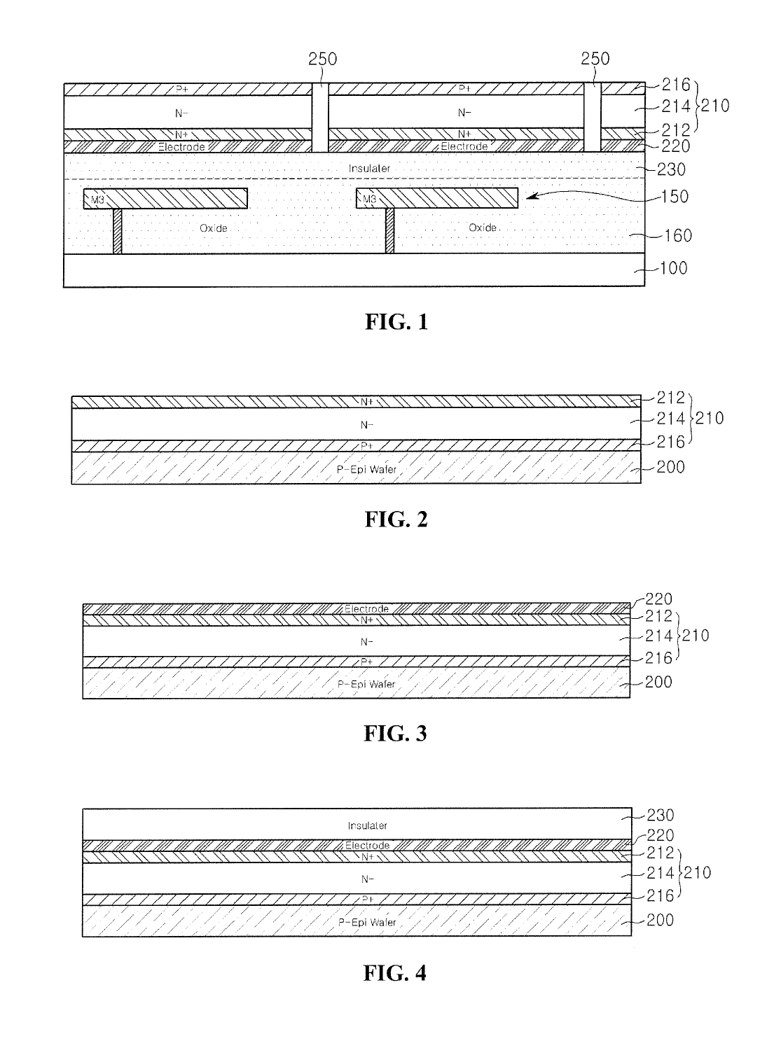

FIG. 1 is a cross-sectional view of an image sensor according to an embodiment.

An image sensor according to an embodiment may include: a first substrate 100 having readout circuitry (not shown); an interconnection 150 over the first substrate 100 and electrically connected to the readout circuitry; an insulating layer 230 over the interconnection 150; an electrode 220 on the insulating layer 230; and an image sensing device 210 on the electrode 220.

The image sensing device 210 may be a photodiode, but, without being limited thereto, may be a photogate, or a combination of the photodiode and the photogate. In this embodiment, it will be described as an example that the photodiode is formed in a crystalline semiconductor layer. However, embodiments are not limited thereto. For example, the photodiode may be formed in an amorphous semiconductor layer.

Unexplained reference numerals in FIG. 1 will be described with reference to the drawings illustrating a method for manufacturing the image sensor below.

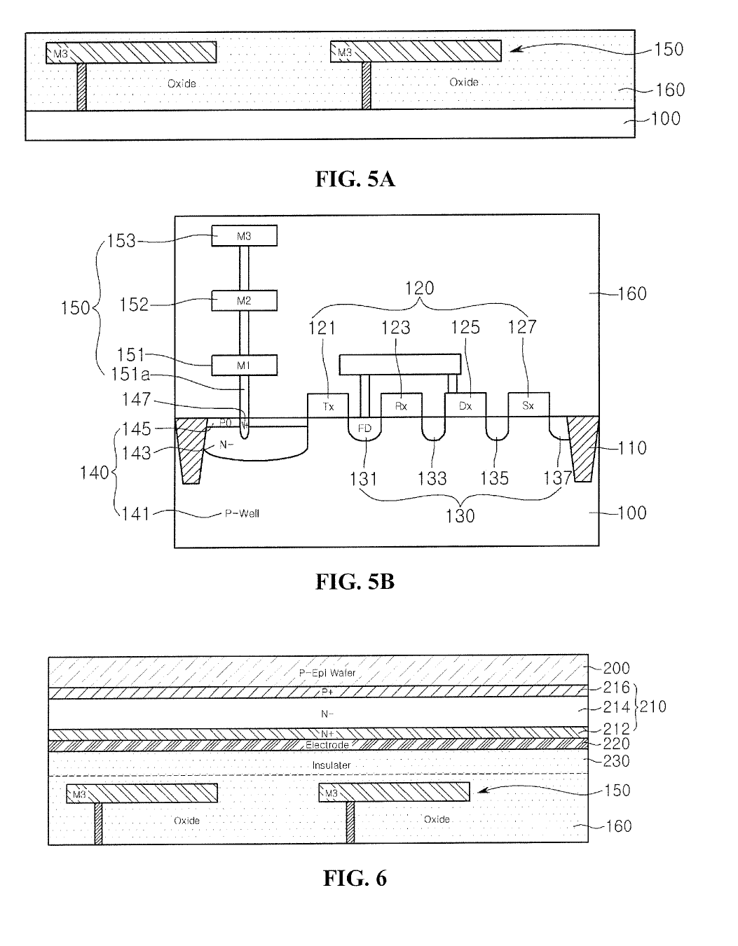

Hereinafter, a method for manufacturing an image sensor according to a first embodiment will be described with reference to FIGS. 2 through 8.

As shown in FIG. 2, an image sensing device 210 is formed on a second substrate 200. For example, a photodiode 210 including a high-concentration P-type conductive layer 216, and a low-concentration N-type conductive layer 214 may be formed by implanting ions into a crystalline semiconductor layer, but is not limited thereto. A high-concentration N+ conductive layer 212 for an ohmic contact may be further formed on the low-concentration N-type conductive layer 214.

Next, as shown in FIG. 3, an electrode 220 is formed on the image sensing device 210. For example, the electrode 220 may be formed on the N+ conductive layer 212 of the image sensing device 210. The electrode 120 may be formed of metal (e.g., Ti/TiN/Al/Ti/TiN), polysilicon, or silicide, but is not limited thereto.

Next, as shown in FIG. 4, an insulating layer 230 is formed on the electrode 220. For example, the insulating layer 230 may be formed of oxide, nitride/oxide or oxide/nitride/oxide, but the material for the insulating layer 230 is not limited thereto.

As shown in FIG. 5A, a first substrate 100 where the interconnection 150 and the readout circuitry 120 are formed is prepared. FIG. 5B is a detailed view according to a first embodiment of the first substrate 100 where the interconnection 150 and the readout circuitry 120 are formed, which will be more fully described below.

As shown in FIG. 5B, the first substrate 100 is prepared, in which the interconnection 150 and the readout circuitry 120 are formed. For example, an active region is defined by forming a device isolation layer 110 in the first substrate 100, and readout circuitry 120 including transistors are formed in the active region. For instance, the readout circuitry 120 may include a transfer transistor (Tx) 121, a reset transistor (Rx) 123, a drive transistor (Dx) 125, and a select transistor (Sx) 127. An ion implantation region 130, including a floating diffusion region (FD) 131 and source/drain regions 133, 135 and 137 for each transistor, may be formed. Also, according to an embodiment, a noise removing circuit (not shown) can be included to improve sensitivity.

The method for manufacturing an image sensor may include forming an electrical junction region 140 in the first substrate 100, and forming a first conductive type connection 147 connected to the interconnection 150 at an upper part of the electrical junction region 140.

For example, the electrical junction region 140 may be a P-N junction 140, but is not limited thereto. For example, the electrical junction region 140 may include a first conductive type ion implantation layer 143 formed on a second conductive type well 141 or a second conductive type epitaxial layer, and a second conductive type ion implantation layer 145 formed on the first conductive type ion implantation layer 143. For example, as shown in FIG. 5B, the P-N junction 140 may be a P0(145)/N−(143)/P−(141) junction, but is not limited thereto. The first substrate 100 may be a second conductive type, but is not limited thereto.

According to an embodiment, the device is designed to provide a potential difference between the source and drain of the transfer transistor (Tx), thus implementing the full dumping of a photo charge. Accordingly, a photo charge generated in the photodiode is dumped to the floating diffusion region, thereby increasing the output image sensitivity.

That is, referring to FIG. 5B, the embodiment forms the electrical junction region 140 in the first substrate 100 including the readout circuit 120 to provide a potential difference between the source and drain of the transfer transistor (Tx) 121, thereby implementing the full dumping of a photo charge.

Thus, unlike the related art case of connecting a photodiode simply to an N+ junction, the embodiment makes it possible to inhibit saturation reduction and sensitivity degradation.

Thereafter, a first conductive type connection 147 is formed between the photodiode and the readout circuit to create a smooth transfer path of a photo charge, thereby making it possible to minimize a dark current source and inhibit saturation reduction and sensitivity degradation.

To this end, the first embodiment may form a first conductive type connection 147 for an ohmic contact on the surface of the P0/N−/P− junction 140. The N+ region (147) may be formed such that it pierces the PO region (145) to contact the N− region (143).

The width of the first conductive type connection 147 may be minimized to inhibit the first conductive type connection 147 from being a leakage source. To this end, the embodiment may perform plug implant after etching a contact hole for a first metal contact 151a, but embodiments are not limited thereto. For example, an ion implantation pattern (not shown) may be formed by another method, and the ion implantation pattern may be used as an ion implantation mask to form the first conductive type connection 147.

That is, a reason why an N+ doping is performed only on a contact formation region is to minimize a dark signal and help the smooth formation of an ohmic contact. If the entire Tx source region is N+ doped like the related art, a dark signal may increase due to an Si surface dangling bond.

An interlayer dielectric 160 may be formed on the first substrate 100, and an interconnection 150 may be formed. The interconnection 150 may include the first metal contact 151a, a first metal 151, a second metal 152, and a third metal 153, but embodiments are not limited thereto.

Next, as shown in FIG. 6, the second substrate is bonded to the first substrate 100 so as to contact the insulating layer 230 with the first substrate 100. For example, in the bonding of the first and second substrates 100 and 200, the insulating layer 230 is interposed therebetween so as to keep the image sensing device 210 from contact with the interconnection 150.

Next, as shown in FIG. 7, the second substrate 200 is removed to leave the image sensing device 210. For example, the second substrate 200 at an upper part of the bonded chip may be cut to expose the P+ layer 216.

Next, as shown in FIG. 8, a device isolation layer 250 may be formed for a pixel-to-pixel isolation. The device isolation layer 250 may be formed through Shallow Trench Isolation (STI) or ion implantation.

Thereafter, the P+ layer 216 at an upper part of the chip is connected to a ground line through a subsequent process.

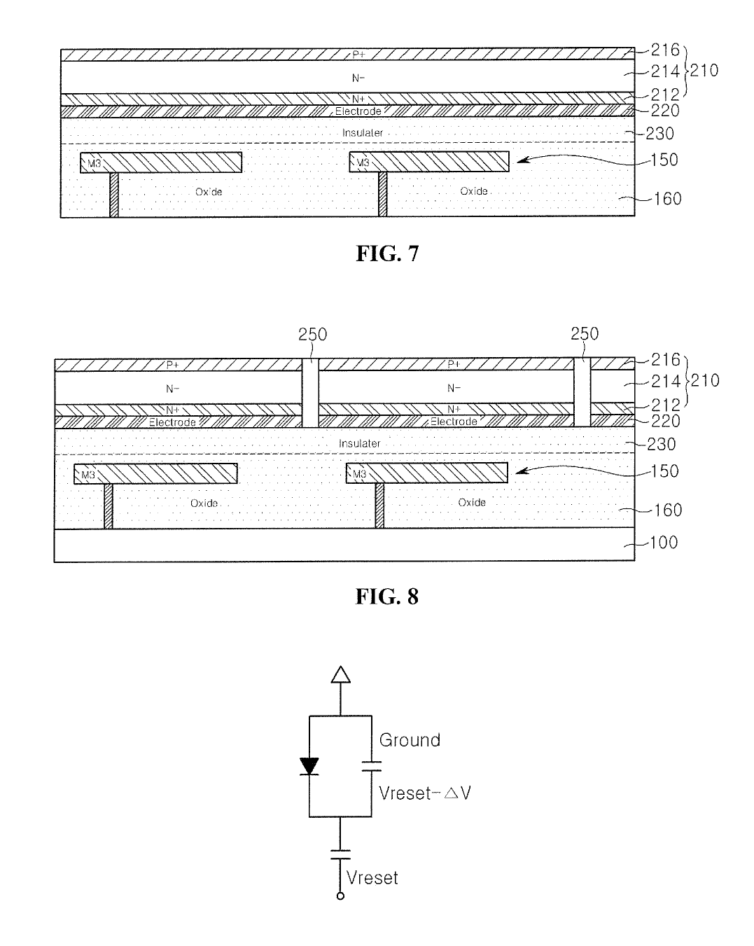

FIG. 9 is an equivalent circuit of the image sensor of FIG. 8, and FIG. 10 shows a voltage distribution upon reset for a pixel operation.

Referring to FIGS. 8 and 10, a voltage of a photodiode is reduced when photo electrons are generated upon light integration, and this is delivered to the readout circuitry 120 of the silicon substrate through a capacitance formed by the insulating layer (Insulator) between the electrode 220 at an upper part of the chip and the interconnection (metal 3). Accordingly, changes of voltage according to the number of electrons generated by light may be sensed, enabling an image signal implementation.

In this case, the height of a transistor in the readout circuitry of the first substrate 100 may be five to fifteen times a distance between the interconnection 150 and the electrode 220 (e.g., the thickness of the insulating layer therebetween), enabling effective delivery of the voltage change according to electrons generated by light to the readout circuitry 120.

According to embodiments of the image sensor and the method for manufacturing the same, the image sensing device at an upper part of the chip and the readout circuitry of the silicon substrate may be connected using a capacitive coupling (i.e. capacitance), omitting a contact process between the image sensing device at an upper part of the chip and the interconnection. Accordingly, the manufacturing process of a 3D image sensor can be simplified, and an increase of a dark current due to formation of a contact may be inhibited.

A method for manufacturing an image sensor according to a second embodiment may adopt the technical features of the first embodiment.

Different features from the first embodiment will be described below.

In the method for manufacturing an image sensor according to the second embodiment unlike the first embodiment, an insulating layer 230 and an electrode 220 may be sequentially formed on the interconnection 150 instead of on the second substrate 200.

The image sensing device 210 may be formed on the second substrate 200, and the first substrate 100 and the second substrate 200 may be bonded to each other so that the electrode 220 may contact the image sensing device 210.

Subsequent processes may adopt the technical features of the first embodiment.

According to the image sensor and the method for manufacturing the same of the second embodiment, the image sensing device at an upper part of the chip and the readout circuitry of the silicon substrate may be connected using a capacitance, omitting a contact process between the image sensing device at an upper part of the chip and the interconnection. Accordingly, the manufacturing process of a 3D image sensor can be simplified, and an increase of a dark current due to formation of a contact may be inhibited.

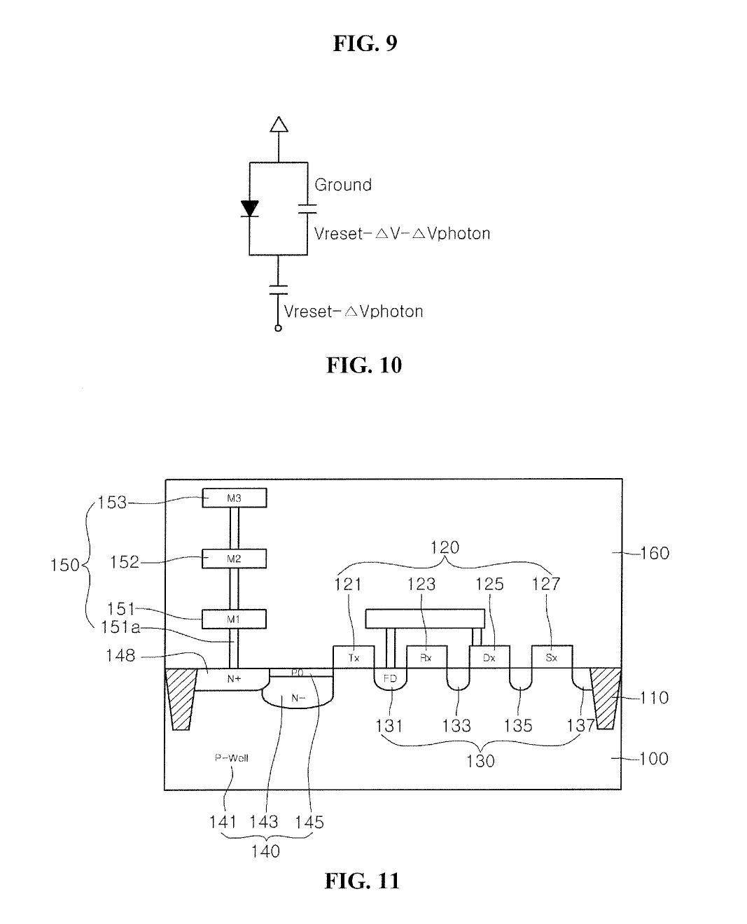

FIG. 11 is a cross-sectional view of an image sensor according to a third embodiment, showing a detailed view of a first substrate where an interconnection 150 is formed.

Similarly to the first embodiment, an image sensor according to the third embodiment may include: a readout circuitry in a first substrate; an interconnection over the first substrate and electrically connected to the readout circuitry; an insulating layer over the interconnection; an electrode on the insulating layer; and an image sensing device on the electrode.

The third embodiment may adopt the technical features of the first embodiment and the second embodiment.

Different from the structure shown in FIG. 5B, the third embodiment has a first conductive type connection 148 formed at one side of an electrical junction region 140.

The N+ connection region 148 may be formed at the P0/N−/P− junction 140 for an ohmic contact. In a process of forming an N+ connection region and a first metal contact 151a, a leakage source may occur. This is because an electric field (EF) may be generated over the Si surface due to operation while a reverse bias is applied to P0/N−/P− junction 140. A crystal defect generated during the contact forming process inside the electric field may become a leakage source.

Also, when the N+ connection region (see reference 147 of FIG. 5B) is formed over the surface of PO/N−/P− junction 140, an electric field may be additionally generated due to N+/P0 junction. This electric field may also become a leakage source.

Therefore, the third embodiment proposes a layout in which the first contact plug 151a is formed in an active region not doped with a PO layer but including N+ connection region 148 that is connected to N-junction 143.

According to the third embodiment, the electric field is not generated on and/or over the Si surface, thereby contributing to reduction in a dark current of a 3-D integrated CIS.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry in a first substrate;
an interconnection over the first substrate and electrically connected to the readout circuitry;
an insulating layer over the interconnection to completely cover the interconnection;
an electrode on the insulating layer; and
an image sensing device on the electrode.

2. The image sensor according to claim 1, wherein the readout circuitry of the first substrate comprises a transistor having a height of about five times to about fifteen times of the distance between the top surface of interconnection and the bottom surface of the electrode.

3. The image sensor according to claim 1, further comprising an electrical junction region at the first substrate and electrically connected to the readout circuitry and the interconnection.

4. The image sensor according to claim 3, wherein the electrical junction region comprises:
a first conductive type ion implantation region at the first substrate; and
a second conductive type ion implantation region on the first conductive type ion implantation region.

5. The image sensor according to claim 3, further comprising a first conductive type connection between the electrical junction region and the interconnection for electrically connecting the interconnection to the electrical junction region.

6. The image sensor according to claim 5, wherein the first conductive type connection is disposed at an upper part of the electrical junction region.

7. The image sensor according to claim 5, wherein the first conductive type connection is disposed at one side of the electrical junction region.

8. The image sensor according to claim 3, wherein the readout circuitry comprises a transistor, wherein the electrical junction region is disposed at a source of the transistor to provide a potential difference between the source and a drain of the transistor.

9. The image sensor according to claim 8, wherein the transistor is a transfer transistor, and an ion implantation concentration of the transistor's source is smaller than an ion implantation concentration of a floating diffusion region at the transistor's drain.

10. A method for manufacturing an image sensor, comprising:
forming a readout circuitry in a first substrate;
forming an interconnection over the first substrate and electrically connected to the readout circuitry;
forming an image sensing device at a second substrate;
sequentially forming an electrode and an insulating layer on the image sensing device; and
bonding the first substrate and the second substrate to contact the insulating layer with the first substrate.

11. The method according to claim 10, further comprising:
forming an electrical junction region at the first substrate, the electrical junction region being electrically connected to the readout circuit,
wherein the bonding of the first substrate and the second substrate comprises interposing the insulating layer and the electrode so as to keep the interconnection from contact with the image sensing device.

12. The method according to claim 11, further comprising:
forming a first conductive type connection between the electrical junction region and the interconnection to electrically connect the interconnection to the electrical junction region,
wherein the forming of the electrical junction region comprises:
forming a first conductive type ion implantation region at the first substrate; and
forming a second conductive type ion implantation region on the first conductive type ion implantation region.

13. The method according to claim 12, wherein the first conductive type connection is formed at an upper part of the electrical junction region.

14. The method according to claim 12, wherein the first conductive type connection is formed at one side of the electrical junction region.

15. A method for manufacturing an image sensor, comprising:
forming a readout circuitry in a first substrate;
forming an interconnection over the first substrate, the interconnection being electrically connected to the readout circuitry;
sequentially forming an insulating layer and an electrode over the interconnection, the insulating layer separating the electrode from the interconnection;
forming an image sensing device at a second substrate; and
bonding the first substrate and the second substrate to contact the electrode with image sensing device.

16. The method according to claim 15, further comprising forming a first conductive type connection between the electrical junction region and the interconnection to electrically connect the interconnection to the electrical junction region,
wherein the forming of the electrical junction region comprises:
forming a first conductive type ion implantation region at the first substrate; and
forming a second conductive type ion implantation region on the first conductive type ion implantation region.

17. The method according to claim 16, wherein the first conductive type connection is formed at an upper part of the electrical junction region.

18. The method according to claim 16, wherein the first conductive type connection is formed at one side of the electrical junction region.
